(19) United States
(12) Patent Application Publication
(10) Pub. No.: US 2025/0365856 A1
(43) Pub. Date: Nov. 27, 2025

(54) VERSATILE HIGH FREQUENCY MONOLITHIC MULTI-LAYERED CIRCUIT BOARD WITH EMBEDDED COAXIAL VIAS USEFUL FOR TESTING OF HIGH FREQUENCY INTEGRATED CIRCUIT DEVICES

(71) Applicant: R&D Circuits, Inc. (dba R&D Altanova), South Plainfield, NJ (US)

(72) Inventors: Quaid Joher Furniturewala, South Plainfield, NJ (US); Syed Raza Rizvi, South Plainfield, NJ (US); Dhananjaya Turpuseema, South Plainfield, NJ (US); Thomas James Smith, South Plainfield, NJ (US)

(21) Appl. No.: 18/670,113

(22) Filed: May 21, 2024

(51) Int. Cl. H05K 1/02; G01R 31/28; H05K 3/00; H05K 3/18

(52) U.S. Cl. CPC H05K 1/024; G01R 31/2818; G01R 31/2822; H05K 1/0222; H05K 1/0242; H05K 1/0298; H05K 3/0047; H05K 3/181

(57) ABSTRACT

With the rapidly increasing frequencies of operation of integrated circuit devices, connection of test signals becomes commensurately difficult. It is beneficial if the delivery of signals can be done in tightly controlled ways such as using transmission lines of constant characteristic impedance over a very broad frequency range. Using a coaxial system to deliver signals as close as possible to a device under test and transitioning to microstrip or stripline at the latest possible time, exceptional performance is possible. The ability to create coaxial vias that perform the transition to microstrip or stripline inside a monolithic multi-layer circuit board that is used as an interposer to make connection to the device under test minimizes interference and mitigates unwanted parasitic reactances at the points of transition.

### BACKGROUND

The present invention relates to systems and methods for reliable, dependable test tooling for high frequency integrated circuit (IC) devices. In particular, improved high frequency interconnection structures for IC device test tooling are provided which are tolerant of dimensional irregularities in multi-layer circuit boards that are routinely used, for example, as elements of interposers used to make connections to the devices to be tested. These circuit boards are created by assembling multiple laminations so as to form a single monolithic structure. Each lamination may have conductors which carry signals, power and ground including shielding structures. These circuit boards, when used to fabricate interposers, are generally specific to a device under test (DUT) and connect the DUT to a test board. The test board is the typical termination point to which external test equipment is connected, where signal and power cables are connected. An interposer then routes these connections from the test board to the DUT so that signals and power can be applied to the DUT.

As the quest for increasingly higher frequency semiconductor parts continues, the problems of accurately delivering test waveforms to and from the parts become very difficult. Performance, especially speed, is significantly affected by the proximity of interworking parts and the need to isolate signal circuits from one another. Further, it is crucial to choose impedances and phase shifts in the transmission lines to deliver minimally distorted signals as close as possible to the connection points at the DUT.

Employing coaxial structures to facilitate signal delivery and provide shielding to the test board is typically achieved through conventional cabling techniques. However, extending these precise and well-defined transmissions from the test board to to the DUT connection points via the interposer is inherently complex due to the electrical and physical properties of the materials used in crafting these inter-connecting circuit boards, e.g., test inter-connectors or interposers.

More particularly, there is a technology change from the dielectric materials used in ordinary coaxial cables to the materials used to make up test boards and interposers. While managing this difficulty may be straightforward at frequencies below 10 GHz, for example, at frequencies above 10 GHz the propagation characteristics of ordinary coaxial structures become troublesome. In particular, care should be taken to ensure that propagation is constrained to a single propagation transverse electro-magnetic mode (TEM) and that multi-mode propagation is prevented. Primarily, this is because different modes propagate at different speeds and, as a result, waveform distortion may be introduced and may compromise testing.

A further difficulty is that dimensional changes, implicit with a change to the dielectric constant of the monolithic multi-layer circuit board materials in which a transmission line is embedded, introduce troubling parasitic reactances and changes in characteristic impedance which can in turn introduce undesired phase shifts and mismatches, leading to waveform distortion.

It is apparent that an urgent need exists for interconnection technologies capable of achieving superior electrical performance when connecting between high frequency integrated circuits and the test board in existing testing station assemblies. This improved interconnection technology accommodates DUTs while providing excellent signal transmission characteristics to and from the test board. Importantly this invention is particularly beneficial for the delivery of differential signals at very high frequencies using coaxial structures embedded in the interposer. A novel manufacturing process creates a monolithic multi-layer circuit board, e.g., a test inter-connector or interposer, that is versatile and durable while limiting the effects of manufacturing uncertainties on testing performance, resulting in more dependable and cost-effective testing performance.

### SUMMARY

To achieve the foregoing and in accordance with the present invention, systems and methods for fabricating circuit boards having embedded coaxial vias for electrically coupling an upper surface signal layer to one or more internal signal layers at a signal connection pad within the circuit board is provided.

In one embodiment, a contact region on one surface of the monolithic multi-layer circuit board used to make an interposer is arranged so as to be aligned with a corresponding contact region associated with a device under test (DUT). On another surface of the interposer, a second contact region is arranged so that it corresponds with a contact region provided on a test board, that is connected to and terminates a suite of test equipment, so that power and signals can be connected to the DUT. The transfer of signals between some of the contact regions is facilitated using embedded coaxial transmission lines in the interposer so as to minimize cross-talk and the effects of interfering signals or extraneous electromagnetic fields as well as the maintenance of a consistent impedance structure as close as possible to the DUT. This allows the transmission path of the signals to and from the DUT via the interposer to be broadband and far less affected by parasitic reactances associated with simple unbalanced and unshielded systems.

In particular, the contact arrangement on the DUT is not generally the same as that contact arrangement on the test board. Continuity of shielded transmission lines brings predictable performance and avoids frequency dependent effects associated with single wire systems. Further, testing of balanced, differential circuits is possible across a much greater bandwidth than can be achieved using single-wire connections. An economic advantage is also obtained by using an adapter that fits between the DUT and the test board that is used to terminate the test equipment being used for the testing.

Revamping a test board to accommodate new cabling and navigate the intricacies of alternating test configurations might negate the financial benefits gained from enhanced device packaging and improved performance of the device under test. Therefore, opting for the reuse of a reliable and verified test arrangement, which incorporates an existing test board, is a more favorable approach. The foregoing advantages are achieved by providing shielded connections between some contact points on a DUT and the corresponding contact points on the test board by using coaxial connecting vias that are routed between them through the monolithic multi-layer circuit board that is an enabling component of an adapter or interposer.

### BRIEF DESCRIPTION OF THE DRAWINGS

In order that the present invention may be more clearly ascertained, some embodiments will now be described, by way of example, with reference to the accompanying drawings, in which:

FIG. 1 illustrates a sectioned view of a monolithic multi-layer circuit board having coaxial vias, according to one or more aspects of the various embodiments;

FIG. 2A shows a preliminary pilot drilling to establish a reference depth in the monolithic multi-layer circuit board of FIG. 1, according to one or more aspects of the various embodiments;

FIG. 2B shows the progression of drilling part way into the subsequent layer of the monolithic multi-layer circuit board of FIG. 1, according to one or more aspects of the various embodiments;

FIG. 3A illustrates finish drilling of the monolithic multi-layer circuit board of FIG. 1 to the external dimension of the coaxial outer conductor, according to one or more aspects of the various embodiments;

FIG. 3B shows the drilling of a pilot hole for the signal layer connection at a signal connection pad of the monolithic multi-layer circuit board of FIG. 1, according to one or more aspects of the various embodiments;

FIG. 4 shows plating on the sides and floor of the hole cut for the outer conductor as well as the cylindrical periphery of the pilot hole cut for the signal conductor of the monolithic multi-layer circuit board of FIG. 1, according to one or more aspects of the various embodiments;

FIG. 5 shows a defined diameter drill used to cut the plated internal size of the outer coaxial conductor as well as ensuring its disconnection from the floor of the hole of the monolithic multi-layer circuit board of FIG. 1, according to one or more aspects of the various embodiments;

FIG. 6A shows the formed coaxial outer conductor after finish drilling with the plated pilot hole for the inner conductor of the coaxial element of the monolithic multi-layer circuit board of FIG. 1, according to one or more aspects of the various embodiments;

FIG. 6B shows the addition of dielectric fill for the cavity formed by the outer conductor of the monolithic multi-layer circuit board of FIG. 1, according to one or more aspects of the various embodiments;

FIGS. 7A & 7B illustrate the re-drilling of the plated pilot hole with a finished-size drill to establish the outer dimension of the inner conductor of the monolithic multi-layer circuit board of FIG. 1, according to one or more aspects of the various embodiments;

FIG. 8 shows the addition of connection lands to the inner and outer conductors and counter-drilling of the plated inner conductor to eliminate surplus conductor length which may contribute to parasitic reactance, according to one or more aspects of the various embodiments; and

FIGS. 9A-9B are flow-charts that describe each sequential step in the making of embedded coaxial vias in a monolithic multi-layered circuit board, according to one or more aspects of the various embodiments.

### DETAILED DESCRIPTION

The present invention will now be described in detail with reference to several embodiments thereof as illustrated in the accompanying drawings. In the following description, numerous specific details are set forth in order to provide a thorough understanding of embodiments of the present invention. It will be apparent, however, to one skilled in the art, that embodiments may be practiced without some or all of these specific details. In other instances, well known process steps and/or structures have not been described in detail in order to not unnecessarily obscure the present invention. The features and advantages of embodiments may be better understood with reference to the drawings and discussions that follow.

Aspects, features and advantages of exemplary embodiments of the present invention will become better understood with regard to the following description in connection with the accompanying drawing(s). It should be apparent to those skilled in the art that the described embodiments of the present invention provided herein are illustrative only and not limiting, having been presented by way of example only. All features disclosed in this description may be replaced by alternative features serving the same or similar purpose, unless expressly stated otherwise. Therefore, numerous other embodiments of the modifications thereof are contemplated as falling within the scope of the present invention as defined herein and equivalents thereto. Hence, use of absolute and/or sequential terms, such as, for example, “will,” “will not,” “shall,” “shall not,” “must,” “must not,” “first,” “initially,” “next,” “subsequently,” “before,” “after,” “lastly,” and “finally,” are not meant to limit the scope of the present invention as the embodiments disclosed herein are merely exemplary.

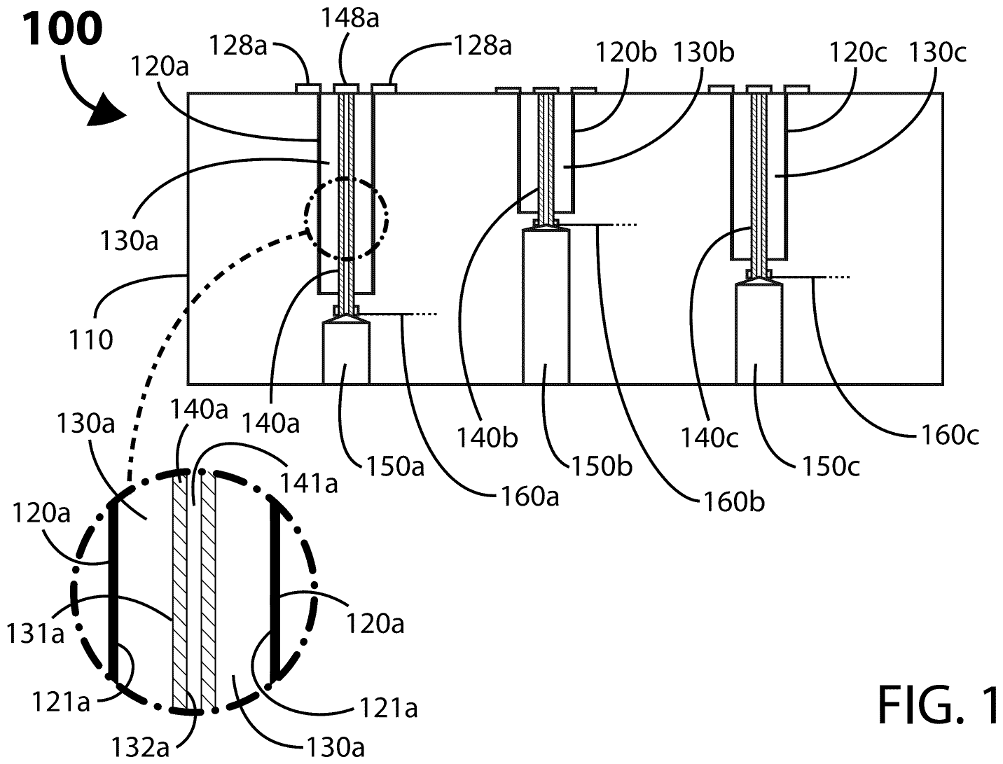

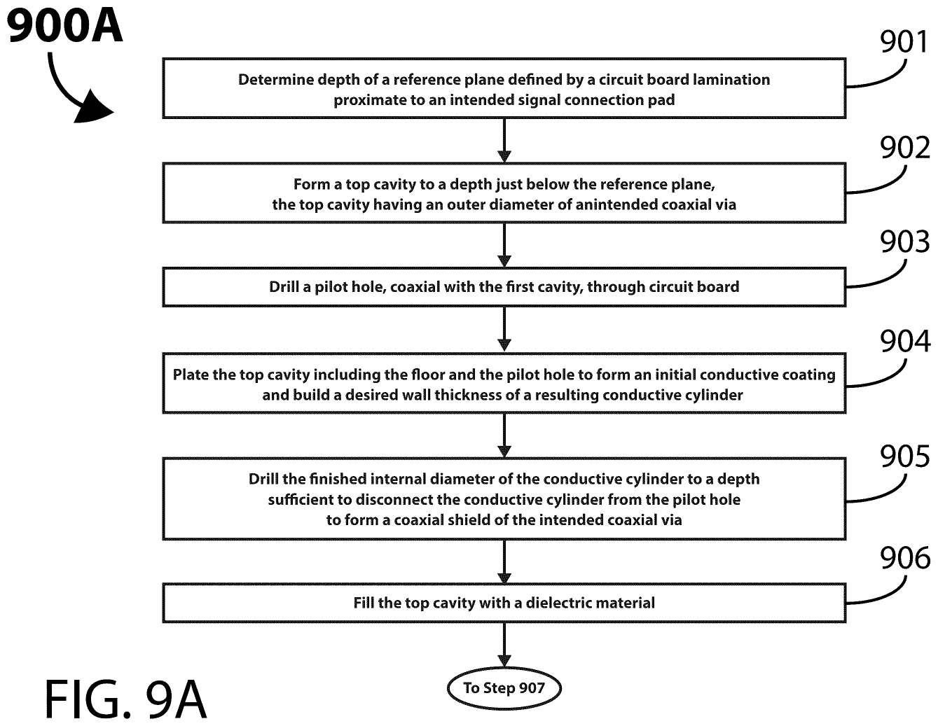

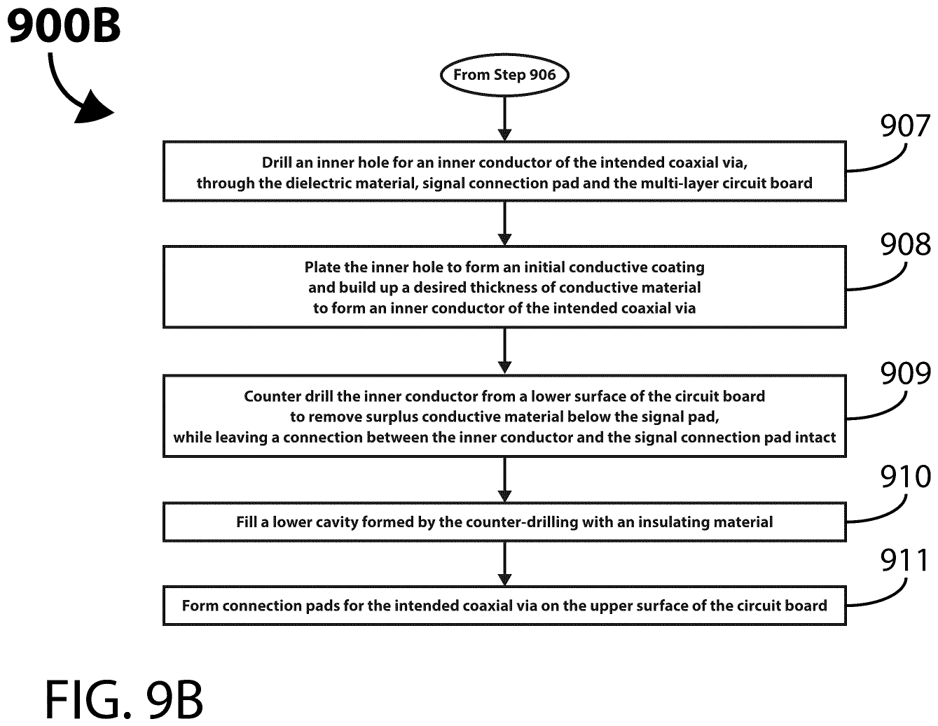

Referring to the drawings, FIG. 1 shows a cross section view of an exemplary monolithic multi-layer circuit board 100 having three coaxial vias formed to connect from the upper surface to their respective buried signal layers 160a, 160b and 160c. The individual layers are not detailed so as to reduce the complexity of the drawing. FIGS. 9A & 9B depict flow-charts 900A & 900B illustrating each exemplary sequential step in the fabrication of embedded coaxial vias in monolithic multi-layered circuit board 100, the steps described in greater detail below. Please note that the figures of the application are illustrative in nature and not necessary drawn to scale.

In one embodiment, the outer cylindrical conductors 120a, 120b and 120c of the coaxial vias are metallized, created by drilling into the circuit board substrate 110 to a target depth and then plating the walls of the drilled holes with a conductive material. These cylindrical outer conductors act as shields where external currents flow on the outer surfaces, while signal currents flow on the inner surfaces, e.g., surface 121a. The inner conductors 140a, 140b and 140c are created by filling the cavities formed by the outer cylindrical conductors with a dielectric material to form insulators 130a, 130b and 130c, and then drilling new holes in this filler material to a predetermined target depth before plating them with a conductive layer. Depending on the chosen dimension of the coaxial via structure, plating of the inner conductors may either create a solid part (filled vias) or may leave cavities within inner conductors 140a, 140b and 140c, e.g., cavity 141a, which may be subsequently filled if required. Contact pads, e.g., pads 128a and 148a, are then provided at the upper surface of circuit board substrate 110 to enable electrical connection to the coaxial vias.

An intermediate step creates temporary structures to facilitate the connection to a buried internal signal layer. These temporary structures are then removed by counter-drilling leaving cavities 150a, 150b and 150c. In some embodiments, these cavities may be filled with an appropriate filler material to improve the integrity of the finished structure.

Plating of drilled cavities by a conductive material creates a cylindrical conductor having inner and outer surfaces. In this example, the outer surface of the outer cylindrical conductor 120a in the coaxial structure is bonded to signal ground. The inner surface 121a may also be bonded to signal ground. The outer surface 131a of the inner conductor 140a is also cylindrical in shape and shares a common axis with the outer cylinder. The inner surface 132a of the plated inner conductor exists in some embodiments, but in other embodiments the inner conductor may be filled. At high radio frequencies, conduction is determined by the skin effect, that is to say that currents flow on the surfaces of the conductors and not in the bulk conductor material. This skin effect depth is the depth below the surface of the conductor where the current density has dropped to 37% (1/e) and 63% of the total current is already accounted for in the conductor surface region. Signal propagation occurs as current flow on the outer surface 131a of the inner conductor (cylinder) is balanced against current flow on the inner surface 121a of the outer conductor. Notionally, there is no signal current that flows on the outside surface of the outer conductor 120a, nor is there current flow inside the inner conductor 140a whether filled or not.

This skin effect means that interfering signals on the outer surface of the outer conductor 120a of the coaxial structure flows to a grounded point when so terminated and does not penetrate the conductor to any significant degree. At 1 GHz in copper, the skin depth is 2.1 μm whilst at 10 GHz this drops to 0.66 μm. Currents inside the structure at surfaces 121a and 131a are essentially isolated from currents outside the structure and this preserves signal integrity. This effect is also important in the operation of the buried signal layers inside the monolithic multi-layer circuit board and will be explained in detail later.

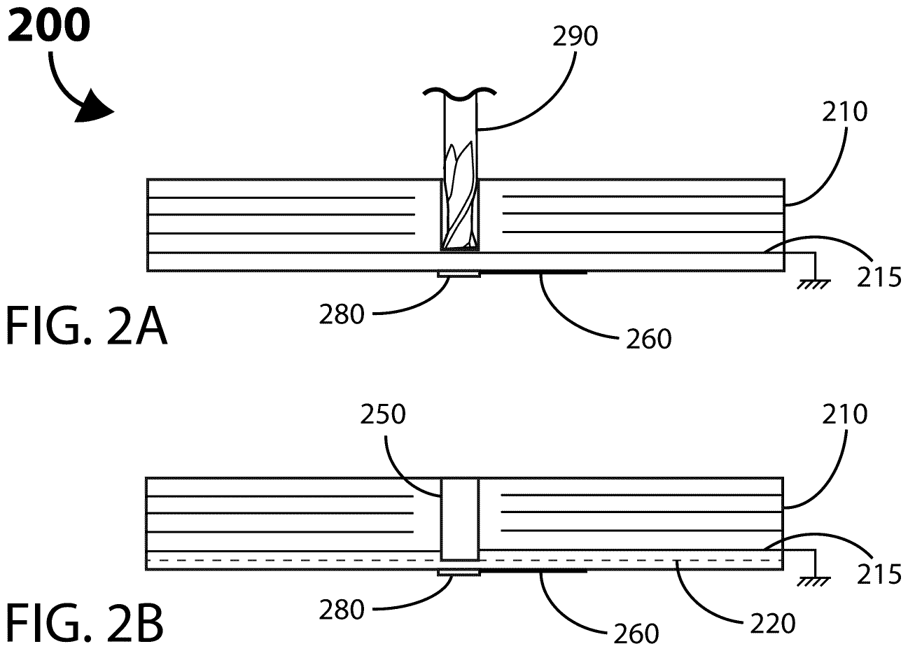

FIG. 2A illustrates a portion 210 of the monolithic multi-layer circuit board 200 used to construct the interposer and shows the layers above the signal conductor 260 and its connection pad 280, to enhance clarity. One or more ground reference plane or layer, e.g., plane 215, exists adjacent to a signal conductor 260 and can be considered to be electrically similar to unrolling the outer conductor of a coaxial structure, forming a microstrip structure. In some embodiments, the layers above and below the signal conductor are ground planes and form a stripline structure with improved immunity to interference and reduced radiation. Dimensions of coaxial structures and stripline or microstrip structures are critical dimensions. In the very high frequency ranges contemplated, upward of 50 GHz, it is important to ensure that signal transmission modes are single mode, with a preference for TEM (transverse electromagnetic) propagation. In particular, guided wave structures that allow other modes (such as waveguide modes) to be excited and to propagate can cause signal distortion because the velocities of propagation differ between modes.

In some embodiments, a first fabrication step 901 in creating a coaxial via which terminates at a buried internal layer or signal conductor requires the precise determination of the drilling depth. To achieve this, the ground reference plane 215 adjacent to the intended signal layer is connected to a voltage source. FIG. 2A illustrates a ground (zero voltage) connection, but this can be any voltage value consistent with the operation of the machine tool used to drill. A drill 290 is selected that is a smaller diameter than the intended final diameter of the outer coaxial cylinder.

Using a back-stop short detection technology the drill 290 is advanced in the plunge direction until the drill contacts the ground reference plane 215, whereupon the motion of the drill 290 in the drilling or plunge direction is stopped automatically. This target depth is recorded and then the drill 290 is advanced so as to penetrate the ground reference plane 215 layer and part way into the lamination preceding the signal conductor 260. The depth of penetration can be varied so long as the drill 290 does not contact the signal conductor. In some embodiments the drill 290 is advanced less than one half of the lamination thickness, while the minimum laminate thickness is 0.004″ and so an advance of up to 0.002″ can be used. FIG. 2B shows the cavity 250 created by the drilling action advanced in depth to median line 220. In some embodiments the drill 290 has a diameter of 0.0098″ and is used to cut this initial pilot hole and to calibrate the machining depth.

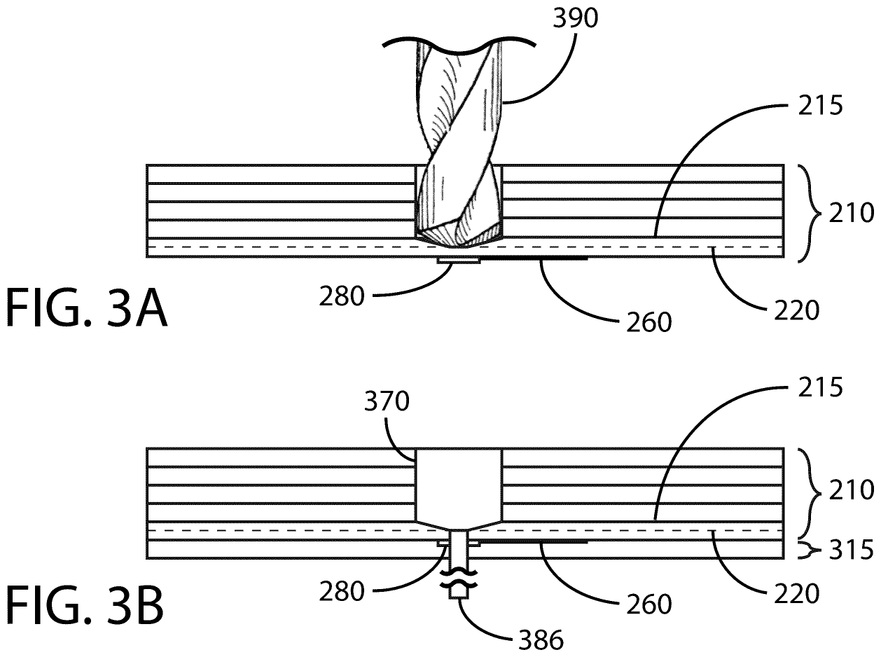

FIG. 3A shows the enlargement of the initial cavity to the final size that creates the outer cylinder of the coaxial structure (see step 902). Drill 390 has a diameter which equals the desired diameter of the outer coaxial cylinder. The drill 390 cuts to the same depth as the pilot drill finish depth without pausing at the ground reference plane 215. This yields a cavity whose depth sets the length of the cylindrical outer conductor of the coaxial via to be created, passing through the ground plane 215 and stopping part way into the laminate close to the median line 220 between the signal conductor 260 and the ground plane 215.

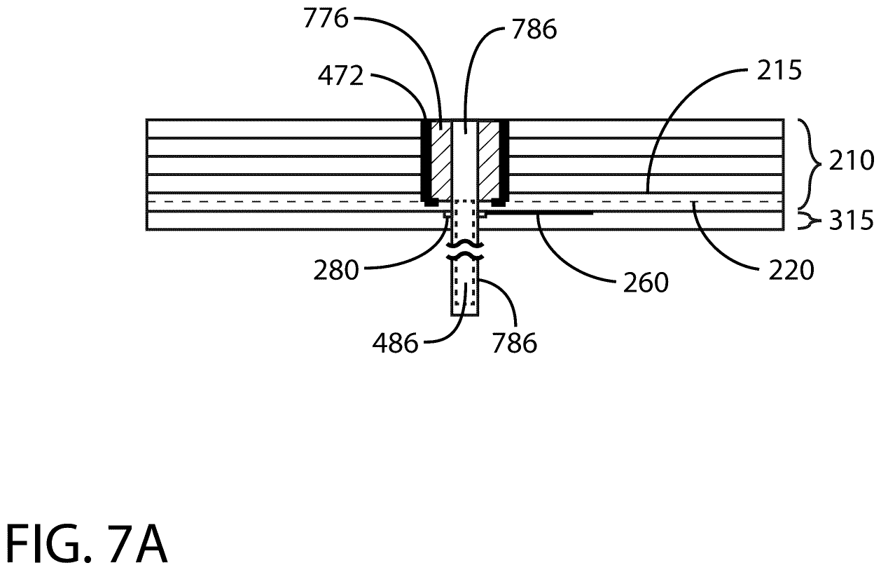

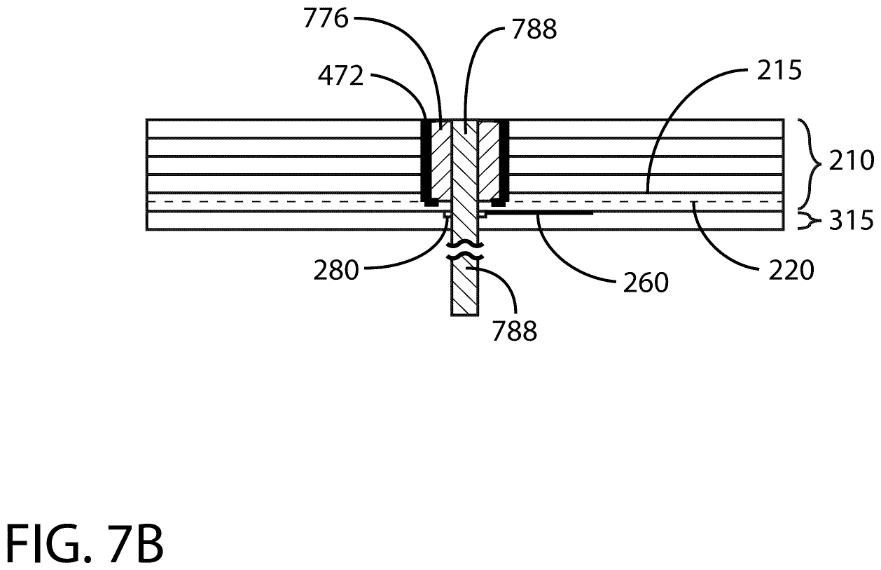

FIG. 3B illustrates an additional lamination 315 of the monolithic multi-layer circuit board below the signal conductor 260. In practice, there may be one or more layers (not shown) below the signal conductor 260. Cavity 370 formed by the drilling action of drill 390 is now finished. A smaller pilot drill (not shown) is now used to drill through the remaining thickness of the monolithic multi-layer circuit board until it exits at the lower surface creating cavity 386 that is coaxial with the larger cavity 370 (see step 903). This cut passes through the connection pad 280 which attaches to the signal conductor 260. In some embodiments a 0.004″ pilot drill is used to create this preliminary pilot cut; the diameter of this pilot drill is chosen to be slightly smaller than the diameter of an inner conductor (see inner conductor cavity 786 of FIG. 7A) of the coaxial via and connection to the signal conductor. In some embodiments, the distance traveled by this pilot drill is recorded and allows the distance from the floor of cavity 370 to the lower surface to be calculated for later use.

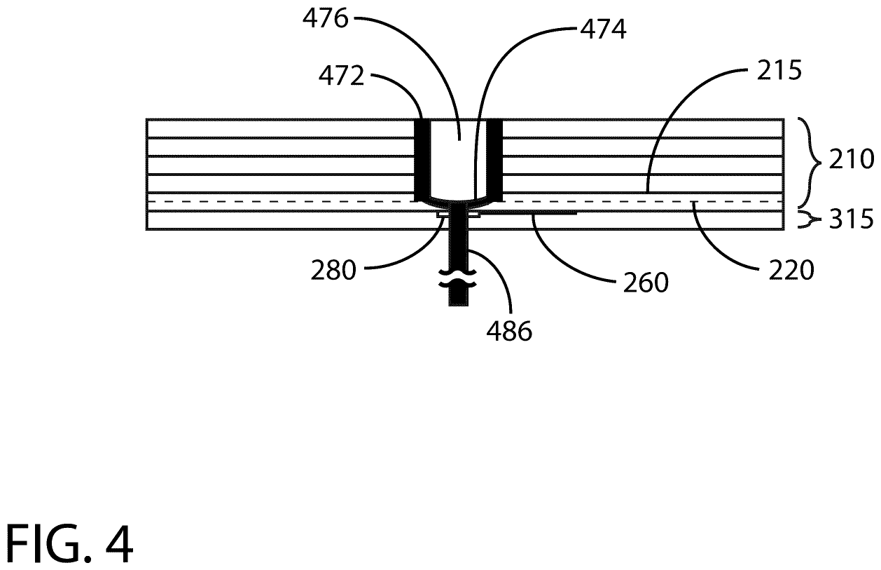

FIG. 4 illustrates the plating of the structure (see step 904). The machined monolithic multi-layer circuit board is treated with an electroless solution which deposits an initial conductive layer on the wall and floor of the first, larger cavity 370 and the smaller cavity 386 formed by the small pilot drill. This plating also creates a connection between the ground plane 215 and the plating on the wall of the first cavity 370. The plating thickness is then increased using an electrolytic plate-up process. At this point there is electrical continuity between the ground plane 215 and the cylindrical outer conductor of the coaxial shield structure being created in the first cavity 370 as well as the conductor 486 filling or partially filling cavity 386 and also signal connection pad 280 and signal conductor 260. Plating continues until the wall thickness of outer conductor 472 in the first cavity 370 has reached the design target inner diameter for the outer cylinder forming the shield of the coaxial section.

Cavity 476 may be already at the target finished diameter or may be slightly smaller. If smaller, this can be enlarged by drilling at a subsequent step. The thickness of the plating on the cavity floor 474 is unimportant since this is to be cut away at a later step to disconnect the ground connection through this floor and the conductor 486 filling or partially filling the cavity 386 to the signal connection pad 280 and signal conductor 260. Laminate 315 is shown as the first of the one or more layers below the signal conductor 260. In some embodiments there may be another signal layer at the bottom of lamination 315 having subsequent laminations beneath that. In some embodiments, a ground plane or a partial ground plane is present on the bottom of lamination 315 so as to convert signal conductor 260 from a microstrip structure into a stripline structure for improved signal transmission performance and greater immunity to interfering signals by limiting the coupling paths above and below the signal conductor. In general, there may be multiple signal layers and multiple ground planes configured so as to create a signal transmission line structure within the monolithic multi-layer circuit board, with some or all embedded signal transmission lines coupled to external connections using coaxial vias.

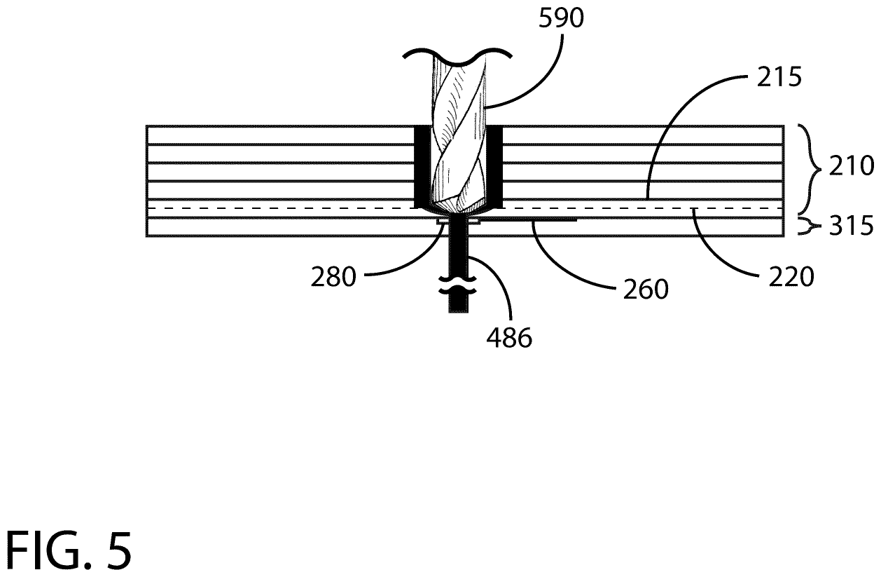

At FIG. 5, drill 590, having the same diameter as the desired finished inner dimension of the outer coaxial cylinder, is used to cut to the same depth as the original empty cavity 370 prior to plating (see step 905). This cuts away much of the plating of floor 474 (see also FIG. 4) and may cut part way into the conductor 486 that fills or partly fills cavity 386. Depending on the quality of the plating process, it can sometimes be necessary to cut slightly deeper to ensure disconnection and, for example, an additional 0.0005″ depth of cut can be applied if needed.

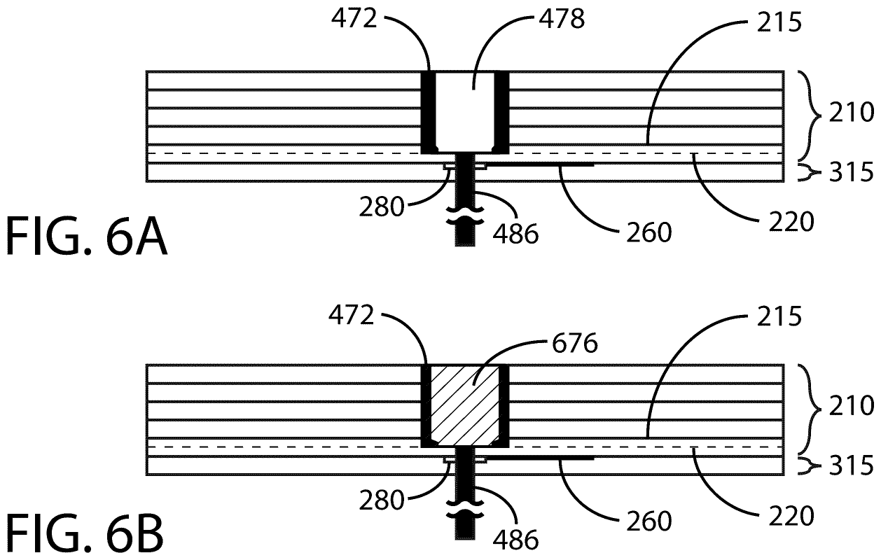

As shown in FIG. 6A, the finished size cavity 478 within the cylindrical outer conductor of the coaxial structure is to be filled with a suitable dielectric material such as an epoxy paste and this is cured forming the dielectric insulator 676 at FIG. 6B (see step 906).

Referring now to FIGS. 7A, 7B & 8, the next step described by FIG. 9B, 907 in forming the coaxial via, is to drill the finished size hole for the inner conductor using a drill (not shown) of the appropriate diameter. This choice of diameter sets the characteristic impedance of the coaxial section since this is determined by the ratio of the two diameters of the inner diameter of the outer cylinder and the outer diameter of the inner conductor taking into account the dielectric constant of the dielectric insulator 676 filling the cavity. As shown in FIG. 7A, the drill cuts a new inner conductor cavity 786 that excises the conductive pillar 486 that was created after the pilot hole was initially drilled through the monolithic multi-layer circuit board, thereby forming the inner dimension for the dielectric insulator 776 of the eventual coaxial via.

FIG. 9B further illustrates step 908 in which an electroless plating method is used to create the initial plating that defines the outer diameter of the inner conductor and an electrolytic plate up process is used to complete the inner conductor 788 for the coaxial via. During this process, the connection between the inner conductor 788 and both the connection pad 280 and signal conductor 260 at the desired lamination of the monolithic multi-layer circuit board is restored. Note that the entire thickness of the monolithic multi-layer circuit board is not shown for clarity, and hence the lower end of inner conductor 788 can be extended to the bottom surface of the monolithic multi-layer circuit board.

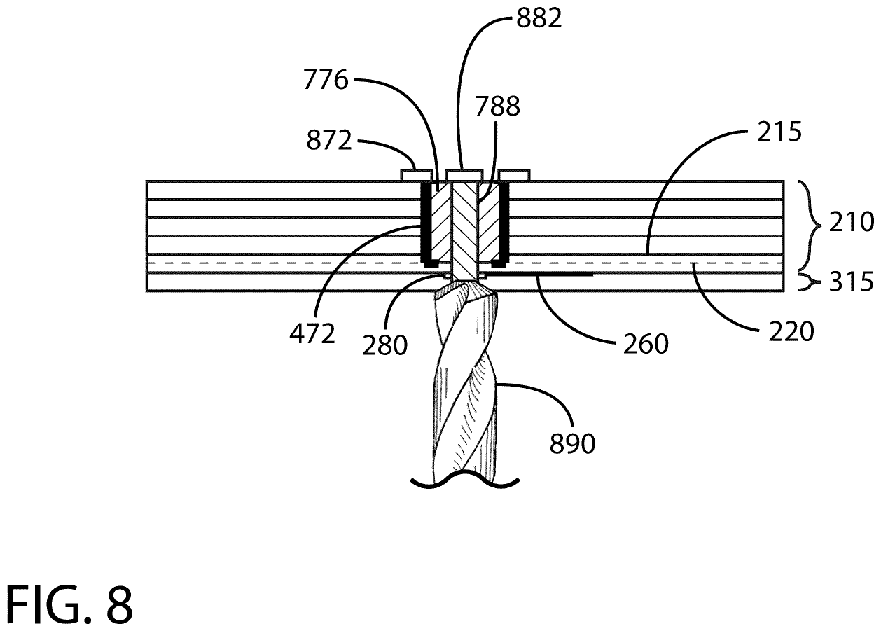

The coaxial via is almost complete at this point. The extended post that runs downward through the remaining thickness of the monolithic multi-layer circuit board from the signal connection pad 280 is however a source of undesirable parasitic reactance and should be disconnected to prevent frequency dependent effects. As shown in FIG. 8, in step 909, a suitably sized drill 890 is used to counter bore, or back-drill, the region of excess from the lower surface of the monolithic multi-layer circuit board which leaves a cavity where the extended lower part of inner conductor 788 has been removed. A suitable filler material such as an epoxy can be used to restore the integrity of the assembly (see step 910).

In some embodiments, the final step 911 is to create the contact points for both inner conductor 788 and outer conductor 472 of this coaxial via by depositing suitable pads 882 and 872, respectively, as required. They may be coplanar or any desired geometrical arrangement subject to predetermined conditions.

Many modifications and permutations of the above-described embodiments are also possible and are contemplated in accordance with the present invention. For example, to displace the contact pads on the bottom of an interposer, the contact pads may be placed asymmetrically at the end of a via so that the via connects to one edge of the contact pad instead of the central region. It is possible to determine the target depth to be drilled, by cutting a coupon at the point of interest from a sacrificial circuit board and the target depth physically measured. This target depth can then be used to manufacture internal vias. The respective length of each of the coaxial vias is determined by the depth of one or more reference planes which, in some embodiments, are positioned one lamination thickness from the intended signal conductors within the substrate. In addition, the above-described embodiments can also be useful for fabricating general purpose monolithic multi-layer circuit boards.

In sum, the disclosed techniques overcome the limitations of traditional methods by enabling the fabrication of transmission lines to carry high frequency signals to and from the DUT with carefully controlled discontinuities such that the impedances are well matched; the reflection coefficient is low, and the return loss is high. This is accomplished by using a monolithic multi-layer circuit board having a number of coaxial vias capable of coupling signals between a surface of the circuit board and one or more internal signal layers of the circuit board to maintain the integrity of the signals. This is particularly important for high performance computing devices operating at 50 GHz and above.

The outer conductive shield of the coaxial vias terminate at their respective reference planes as a signal ground and the inner signal conductors terminate at corresponding internal signal layers located, for example, one or more lamination depth(s) below the reference plane. A dielectric filler is used to maintain the structural and electrical integrity of the coaxial section.

The advantages include the ability to transition from a coaxial transmission line to a microstrip or stripline structure at an internal layer within a monolithic multi-layer circuit board, and the minimization of reflections and cross-talk between signal channels. This results in a reduced degradation of performance that is often associated with more primitive systems and methods and, further, improves simulation performance.

1. In some embodiments, a method for fabricating a monolithic multi-layered circuit board having at least one internal coaxial via comprises determining a target depth of an outer conductor for an internal coaxial via of the monolithic multi-layered circuit board, wherein the target depth is above an internal signal layer of the monolithic multi-layered circuit board, fabricating the outer conductor to the target depth, fabricating a dielectric insulator for the internal coaxial via, and fabricating an inner conductor for the internal coaxial via, wherein the inner conductor is electrically coupled to a signal connection pad located on the internal signal layer.

2. The method of clause 1 further comprising removing any excess portion of the inner conductor below the internal signal layer, while leaving a connection between the inner conductor and the signal connection pad intact.

3. The method of any of clauses 1-2, wherein determining the target depth includes determining a depth of a reference plane defined by a reference layer of the circuit board proximate to an intended signal connection pad located on the internal signal layer, fabricating the outer conductor includes forming a top cavity to the target depth, the top cavity having an outer diameter of the coaxial via, forming a pilot hole, coaxial with the top cavity, through a remainder of the circuit board, coating the top cavity including a floor of the top cavity and the pilot hole to form a conductive cylinder, and drilling the conductive cylinder to a depth sufficient to disconnect the conductive cylinder from the pilot hole thereby forming the outer conductor of the internal coaxial via, fabricating the dielectric insulator includes filling the top cavity with a dielectric material, and fabricating the inner conductor includes forming an inner hole through the dielectric material for housing the inner conductor, wherein the inner hole is a through hole penetrating the signal connection pad and the remainder of the monolithic multi-layered circuit board, and coating the inner hole with a conductive material to form the inner conductor.

4. The method of any of clauses 1-3, wherein the top cavity is formed using a drill and wherein the depth of the reference plane is determined by electrical continuity between the reference plane and the drill.

5. The method of any of clauses 1-4, wherein the conductive cylinder is initially formed by electroless plating and wherein the conductive cylinder is built to a desired wall thickness by electroplating.

6. The method of any of clauses 1-5, wherein removal of the excess portion of the inner conductor includes counter-drilling from a bottom surface of the monolithic multi-layered circuit board.

7. The method of any of clauses 1-6, further comprising filling a lower cavity formed by the counter-drilling with an insulating material.

8. The method of any of clauses 1-7, wherein the inner conductor is initially formed by electroless plating and wherein the inner conductor is built to a desired thickness by electroplating.

9. The method of any of clauses 1-8 further comprising forming one or more connection pads for the internal coaxial via on an upper surface of the monolithic multi-layered circuit board.

10. The method of any of clauses 1-8, wherein the monolithic multi-layered circuit board is part of a test system interposer for testing semiconductor devices.

11. The method of any of clauses 1-8, wherein the target depth is determined by measuring a depth of the internal signal layer from an upper surface of the monolithic multi-layered circuit board using a cross-sectioned sacrificial sample monolithic multi-layered circuit board.

12. In some embodiments, a monolithic multi-layered circuit board having one or more internal coaxial vias for electrically coupling an upper surface layer to one or more internal signal layers within the monolithic multi-layered circuit board, wherein each of the one or more internal coaxial vias comprises an upper cavity housing an outer conductor, wherein a bottom of the upper cavity is at a target depth within the circuit board, wherein the target depth is above an internal signal layer of the monolithic multi-layered circuit board, and wherein a diameter of the upper cavity determines an outer diameter of the outer conductor, an inner conductor configured to electrically transmit a signal from the upper surface layer to the internal signal layer, and a dielectric insulator located between the coaxial shield and the inner conductor.

13. The monolithic multi-layered circuit board of clause 12, wherein the upper cavity is formed using a drill, wherein the target depth is determined relative to a reference plane, and wherein the reference plane is determined by electrical continuity between the reference plane and the drill.

14. The monolithic multi-layered circuit board of clauses 12 or 13, wherein the outer conductor is initially formed by electroless plating and wherein the outer conductor is built to a desired wall thickness by electroplating.

15. The monolithic multi-layered circuit board of any of clauses 12-14, wherein a lower end of the inner conductor is formed by counter drilling from a bottom surface of the monolithic multi-layered circuit board.

16. The monolithic multi-layered circuit board of any of clauses 12-15, wherein a lower cavity between the lower end of the inner conductor and the bottom surface of the circuit board is filled with an insulating material.

17. The monolithic multi-layered circuit board of any of clauses 12-16, wherein the inner conductor is initially formed by electroless plating and wherein the inner conductor is built to a desired thickness by electroplating.

18. The monolithic multi-layered circuit board of any of clauses 12-17 further comprises a plurality of connection pads on the upper surface of the circuit board for the one or more coaxial vias.

19. The monolithic multi-layered circuit board of any of clauses 12-18, wherein the monolithic multi-layered circuit board is part of a test system interposer for testing semiconductor devices.

20. The monolithic multi-layered circuit board of any of clauses 12-19, wherein the target depth of the upper cavity is determined by measuring a depth of the internal signal layer from the upper surface layer using a cross-sectioned sacrificial sample monolithic multi-layered circuit board.

While this invention has been described in terms of several embodiments, there are alterations, modifications, permutations, and substitute equivalents, which fall within the scope of this invention. For example, many modifications are possible and the above-described features from the various embodiments can be useful alone or in combination. Although sub-section titles have been provided to aid in the description of the invention, these titles are merely illustrative and are not intended to limit the scope of the present invention.

It should also be noted that there are many alternative ways of implementing the methods and apparatuses of the present invention. It is therefore intended that the following appended claims be interpreted as including all such alterations, modifications, permutations, and substitute equivalents as fall within the true spirit and scope of the present invention.

What is claimed is:

1. A method for fabricating a monolithic multi-layered circuit board having at least one internal coaxial via, the method comprising:
determining a target depth of an outer conductor for an internal coaxial via of the monolithic multi-layered circuit board, wherein the target depth is above an internal signal layer of the monolithic multi-layered circuit board;
fabricating the outer conductor to the target depth;
fabricating a dielectric insulator for the internal coaxial via; and
fabricating an inner conductor for the internal coaxial via, wherein the inner conductor is electrically coupled to a signal connection pad located on the internal signal layer.

2. The method of claim 1 further comprising removing any excess portion of the inner conductor below the internal signal layer, while leaving a connection between the inner conductor and the signal connection pad intact.

3. The method of claim 1 wherein:
determining the target depth includes determining a depth of a reference plane defined by a reference layer of the monolithic multi-layered circuit board proximate to the signal connection pad;
fabricating the outer conductor comprises:
forming a top cavity to the target depth, the top cavity having an outer diameter of the internal coaxial via;
forming a pilot hole, coaxial with the top cavity, through a remainder of the monolithic multi-layered circuit board;
coating the top cavity including a floor of the top cavity and the pilot hole to form a conductive cylinder; and
drilling the conductive cylinder to a depth sufficient to disconnect the conductive cylinder from the pilot hole thereby forming the outer conductor of the internal coaxial via;
fabricating the dielectric insulator includes filling the top cavity with a dielectric material; and
fabricating the inner conductor includes:
forming an inner hole through the dielectric material for housing the inner conductor, wherein the inner hole is a through hole penetrating the signal connection pad and the remainder of the monolithic multi-layered circuit board; and
coating the inner hole with a conductive material to form the inner conductor.

4. The method of claim 3, wherein the top cavity is formed using a drill and wherein the depth of the reference plane is determined by electrical continuity between the reference plane and the drill.

5. The method of claim 3, wherein the conductive cylinder is initially formed by electroless plating and wherein the conductive cylinder is built to a desired wall thickness by electroplating.

6. The method of claim 2, wherein removal of the excess portion of the inner conductor below the signal connection pad includes counter-drilling from a bottom surface of the monolithic multi-layered circuit board.

7. The method of claim 6 further comprising filling a lower cavity formed by the counter-drilling with an insulating material.

8. The method of claim 3, wherein the inner conductor is initially formed by electroless plating and wherein the inner conductor is built to a desired thickness by electroplating.

9. The method of claim 1 further comprising forming one or more upper connection pads for the internal coaxial via on an upper surface of the monolithic multi-layered circuit board.

10. The method of claim 1, wherein the monolithic multi-layered circuit board is part of a test system interposer for testing semiconductor devices.

11. The method of claim 1, wherein the target depth is determined by measuring a depth of the internal signal layer from an upper surface of the monolithic multi-layered circuit board using a cross-sectioned sacrificial sample monolithic multi-layered circuit board.

12. A monolithic multi-layered circuit board having one or more internal coaxial vias for electrically coupling an upper surface layer to one or more internal signal layers within the monolithic multi-layered circuit board, wherein each of the one or more internal coaxial vias comprises:
an upper cavity housing an outer conductor, wherein a bottom of the upper cavity is at a target depth within the monolithic multi-layered circuit board, wherein the target depth is above an internal signal layer of the monolithic multi-layered circuit board, and wherein a diameter of the upper cavity determines an outer diameter of the outer conductor;
an inner conductor configured to electrically transmit a signal from the upper surface layer to the internal signal layer; and
a dielectric insulator located between the outer conductor and the inner conductor.

13. The monolithic multi-layered circuit board of claim 12, wherein the upper cavity is formed using a drill, wherein the target depth is determined relative to a reference plane, and wherein the reference plane is determined by electrical continuity between the reference plane and the drill.

14. The monolithic multi-layered circuit board of claim 12, wherein the outer conductor is initially formed by electroless plating and wherein the outer conductor is built to a desired wall thickness by electroplating.

15. The monolithic multi-layered circuit board of claim 12, wherein a lower end of the inner conductor is formed by removing the excess below the signal connection pad by counter drilling from a bottom surface of the monolithic multi-layered circuit board.

16. The monolithic multi-layered circuit board of claim 15, wherein a lower cavity between the lower end of the inner conductor and the bottom surface of the monolithic multi-layered circuit board is filled with an insulating material.

17. The monolithic multi-layered circuit board of claim 12, wherein the inner conductor is initially formed by electroless plating and wherein the inner conductor is built to a desired thickness by electroplating.

18. The monolithic multi-layered circuit board of claim 12, further comprising a plurality of upper connection pads on the upper surface of the monolithic multi-layered circuit board for the one or more internal coaxial vias.

19. The monolithic multi-layered circuit board of claim 12, wherein the monolithic multi-layered circuit board is part of a test system interposer for testing semiconductor devices.

20. The monolithic multi-layered circuit board of claim 12, wherein the target depth of the upper cavity is determined by measuring a depth of the internal signal layer from the upper surface layer using a cross-sectioned sacrificial sample monolithic multi-layered circuit board.
